(19) United States
(12) Patent Application Publication
(10) Pub. No.: US 2004/0150074 A1
(43) Pub. Date: Aug. 5, 2004

(54) Anti-reflective coating (ARC) material, semiconductor product with an ARC layer and method of coating a semiconductor product with an ARC layer

(76) Inventors: Steffen Hornig, Dresden (DE); Dietmar Ganz, Aschaffenburg (DE)

Correspondence Address: LERNER AND GREENBERG, P.A., POST OFFICE BOX 2480, HOLLYWOOD, FL, 33022-2480, US

(21) Appl. No.: 10/646,206

(22) Filed: Aug. 22, 2003

Related U.S. Application Data
(63) Continuation of application No. PCT/EP02/01506, filed on Feb. 13, 2002.

(30) Foreign Application Priority Data
Feb. 22, 2001 (EP) 01104284.3

(51) Int. Cl. H01L 23/58; H01L 21/4763; H01L 21/31

(52) U.S. Cl. 257/632; 438/636

(57) ABSTRACT

A semiconductor product has an anti-reflective coating layer covering a semiconductor substrate. The ARC layer is formed of a matrix substance and of nanocrystalline particles of another material than the matrix substance. The nanocrystalline particles absorb light via the quantum size effect, that is, the novel kind of ARC layer is an absorbing ARC layer.

### CROSS-REFERENCE TO RELATED APPLICATION

This application is a continuation of copending International Application No. PCT/EP02/01506, filed Feb. 13, 2002, which designated the United States and which was published in English.

### BACKGROUND OF THE INVENTION

### FIELD OF THE INVENTION

The invention lies in the semiconductor technology field and pertains, more particularly, to an anti-reflective coating (ARC) material for coating a semiconductor product. The anti-reflective coating material is made of a matrix substance and of nanocrystalline particles of another material than the matrix substance.

The invention further pertains to a method of producing an anti-reflective coating material by:

providing a matrix material and providing nano-crystalline particles and

mixing the matrix material and the nano-crystalline particles to form the anti-reflective coating material.

The invention also refers to a semiconductor product comprising a substrate having a surface with a layer of an anti-reflective coating material on the surface and to a method of coating a semiconductor product with the ARC material.

In the production of semiconductor products such as integrated circuits, wafers are subjected to a multitude of process steps such as etching, doping and deposition, for instance. Lateral structures of integrated circuits are created by lithography, the semiconductor products being exposed to UV light through a mask pattern. A resist layer on top of the semiconductor product is then etched, thereby either exposed areas or non-exposed areas of the resist layer being removed.

Due to the small depth of the resist layer and the different refractive indexes of the resist layer and the underlying substrate, reflections of exposure light and interferences in the resist layer occur. As a consequence, lateral structures created by lithography tend to deviate from their predefined dimensions.

Diminution of these deviations is achieved by first forming an anti-reflective coating layer, an ARC layer, before forming the resist layer. There are known ARC layers extinguishing reflections by destructive interference of light reflected at the upper and the lower surface of the ARC layer. Other ARC layers reduce reflection by absorption of incoming light.

Another field of the art knows of nanocrystalline particles with particle sizes less than 100 nanometers. They are used for surfaces easy to clean—these surfaces preferably containing fluorine—or for the production of anti-scratch coatings.

### SUMMARY OF THE INVENTION

It is accordingly an object of the invention to provide an anti-reflective coating (ARC) for a semiconductor product and a semiconductor with an ARC layer which overcome the above-mentioned disadvantages of the heretofore-known devices and methods of this general type and which provides for a new kind of anti-reflective coating material for coating a semiconductor product or a layer on a semiconductor product to form an ARC layer, particularly an ARC layer of improved properties compared to prior art ARC layers.

With the foregoing and other objects in view there is provided, in accordance with the invention, a semiconductor processing method in which a semiconductor product is coated with an anti-reflective coating material formed of a matrix substance and of nanocrystalline particles of a material different from the matrix substance. The nanocrystalline particles absorb light via the quantum size effect. As a result, the ARC absorbs light energy.

With the above and other objects in view there is also provided, in accordance with the invention, a semiconductor product, comprising:

a substrate having a surface;

a layer of an anti-reflective coating material formed on said surface;

said anti-reflective coating material comprising a matrix substance and nanocrystalline particles of a material different from said matrix substance, and said nanocrystalline particles being configured to absorb light via the quantum size effect.

In other words, the objects of the invention are achieved with an anti-reflective coating in which the nanocrystalline particles absorb light via the quantum size effect. According to the invention, light absorption in the ARC layer is achieved by using the quantum size effect. According to this effect, energy levels within the band gap of the ambient material, that is the matrix substance, are created. Electrons on both sides of the band gap may occupy these additional energy levels, thereby absorbing photons of the exposure light. By using this effect for light absorption in nanocrystalline particles of an ARC layer material, a new kind of ARC layer working primarily by absorption is provided. Furthermore, as nanocrystalline particles are too small to cause wave reflections, disturbing reflected beams arising from the ARC layer material are suppressed.

With respect to a semiconductor product the product comprises a substrate having a surface and the anti-reflective coating layer arranged on said surface.

Preferably, the size of the nanocrystalline particles is less than 100 nanometers in diameter on average. In particular, average particle sizes of less than a quarter of the wavelength of 284, 193, 157 or 127 nm of UV exposure light are preferred.

In accordance with another embodiment of the invention, the material of the particles is chosen corresponding to a predefined wavelength absorbed via the quantum size effect. Depending on the band structure including the band gaps of the matrix substance and the wavelength to be absorbed, the material of the nanocrystalline particles is chosen such that additional energy levels within the band gaps with predefined distance to the valence band or the conduction band are created, the predefined distance corresponding to the wavelength to be absorbed. Preferably, this wavelength is in the UV range.

According to a preferred embodiment, the matrix substance and the material and the concentration of the particles are chosen corresponding to a refractive index of the ARC material. These parameters are chosen such that a refractive index granting maximum light entrance into the ARC layer is achieved. Hence, maximum absorption within the ARC layer by means of the nanocrystalline particles is granted.

According to another embodiment, the material and the concentration of the particles are choosing corresponding to a degree of absorption. The degree of absorption may depend on the thickness of the ARC layer and, of course, on the wavelength to be absorbed.

According to another embodiment, the matrix substance and the size and the concentration of the particles are chosen corresponding to a viscosity value. An ARC layer is formed by coating a semiconductor product, especially a semiconductor wafer or flat panel, with an ARC layer precursor substance.

The ARC layer precursor substance consists of the compounds of the ARC layer as well as the solvent allowing to spin on the ARC layer precursor substance onto a rotating semiconductor product. The amount of solvent in the ARC layer is adjusting its viscosity. When material is spun on, the temperature of the material itself is adjusted in order to optimise the spin process, the uniformity of the final layer on the substrate and the material consumption. The adjusted temperature is controlled during the whole spin process in order to guarantee the reliability of the procedure. The spin process is finished when the layer on the substrate has reached a stable condition in terms of drying. Right after the spin process at least one or more heating processes are applied in order to finalise the process of film creation. However, according to this embodiment, further the matrix substance and the size and the concentration of the particles are adjusted in addition with view to a viscosity value.

According to another embodiment, the matrix substance and the material and the concentration of the particles are chosen corresponding to an etch resistance of a dry etch process for etching semiconductor substrates. When a semiconductor product comprising an ARC layer and a resist layer above the ARC layer is etched, etching is proceeded in order to pattern the substrate of the ARC layer in the same way as the pattern mask itself. Precise shaping of three-dimensional structures requires a high etch resistance of the etching mask, that is the resist, and/or of the ARC layer. By carefully choosing the composition of the ARC layer, even this parameter may be controlled.

Preferably, the matrix substance is an organic resin or a silicate. Alternatively, an oxide such as silicon oxide or titanium oxide is preferred.

As to the material of the particles, preferably a metal oxide, a metal sulphide or a perovscite material is chosen. In particular, tin oxide, titanium oxide or cadmium sulphide are preferred. However, there is a lot of other substances with individual band structures leading to appropriate energy levels within the band gap of the matrix substance. Especially oxides and oxide mixtures of metals like Mg, Ca, Ba, Sr, Al, Ga, In, Si, Ge, Ti, Sn, Pb, Sb, Be, Te, Zr, Hf, Nb, Ta, Cr, Mo, W, Mn, Fe, Ru, Co, Rh, Ni, Pd, Zn, Cd, La and of rare earth metals may be taken into account.

Preferably, the ARC layer contains between 3 and 70% per volume of nanocrystalline particles. The broad range of composition even with respect to the matrix to particle ratio contributes to a most flexible adjustment of the aforementioned parameters.

According to an advanced embodiment of the invention, the ARC layer contains nanocrystalline particles of at least two different materials. Thereby, different ranges of wavelengths may be absorbed. By providing different kinds of particles, a predefined absorption profile may be shaped. Furthermore, fine adjustment of absorption profile may be achieved by choosing particles of a predefined average size.

An anti-reflective coating material according to the invention may be used for covering a semiconductor substrate to be patterned or a layer to be patterned on a semiconductor substrate to form an anti-reflective coating layer dimishing light reflection of exposure light.

With view to the initially mentioned method of producing an anti-reflective coating material the object is solved by using nano-crystalline particles which absorb light via the quantum size effect.

Preferrably the kind of the nano-crystalline particles and/or the concentration of the nano-crystalline particles in the matrix material are chosen such that an anti-reflective coating material having an adjusted refractive index is formed. In particular, by choosing the kind and/or the concentration of the nano-crystalline particles, such a refractive index is adjusted which depends on the refractive index of a resist layer to be applied onto the anti-reflective coating material and/or which depends on the refractive index of a semiconductor substrate to be patterned or of a layer to be patterned on a semiconductor substrate.

With view to the semiconductor product initially described the object of the invention is solved by providing an anti-reflective coating material on the surface which is an anti-reflective coating material according to the invention, that is by providing an anti-reflective coating material which absorbs light via the quantum size effect.

Preferably the semiconductor product comprises a resist layer on top of the ARC layer, the resist layer preferably being made of an organic material.

When the kind and/or the concentration of the nano-crystalline particles are chosen to adjust such a refractive index of the anti-reflective coating material which depends on the refractive index of a resist layer to be applied onto the anti-reflective coating material, light reflection on top of the ARC material layer is reduced. Hence, at the intermediate surface between the resist layer and the ARC material layer, most part of incoming light is entering the ARC material layer material and is being absorbed by the nanocrystalline particles.

Other features which are considered as characteristic for the invention are set forth in the appended claims.

Although the invention is illustrated and described herein as embodied in anti-reflective coating material, semiconductor product with an ARC layer and a method of coating a semiconductor product with an ARC layer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic side view of a semiconductor product according to prior art;

FIG. 2 is a similar view of a semiconductor product according to the present invention; and

FIG. 3 is a diagram illustrating a method of forming and applying an anti-reflective coating material according to the invention.

### DESCRIPTION OF THE PREFERRED EMBODIMENTS

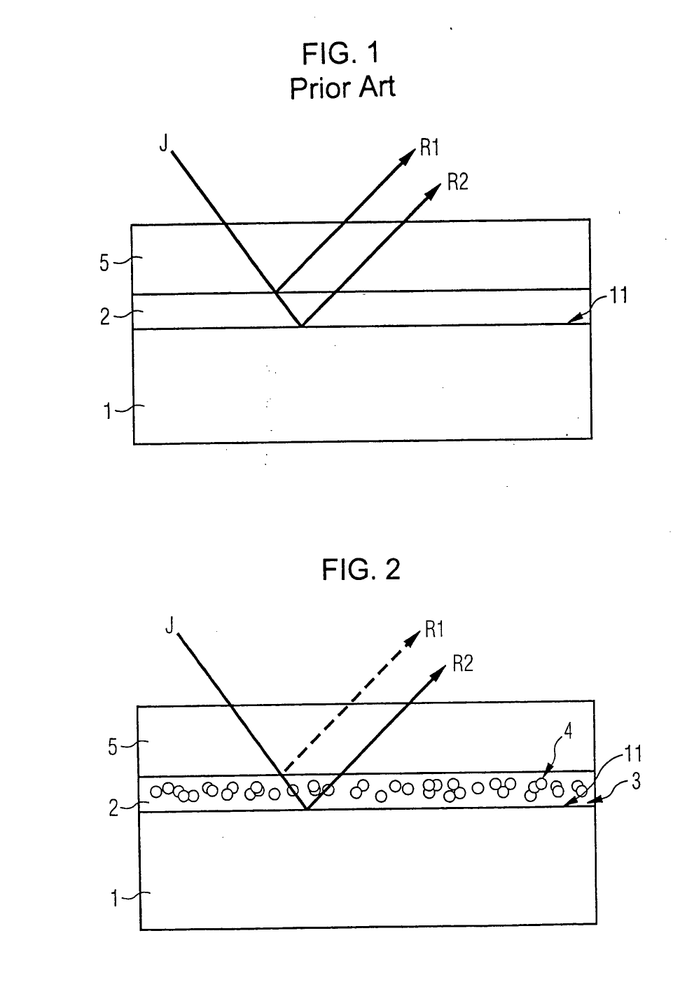

Referring now to the figures of the drawing in detail and first, particularly, to FIG. 1 thereof, there is shown an incoming light beam J entering the resist layer 5. The beam J is partially reflected at the intermediate surface or boundary between the resist layer and an ARC layer 2. This first reflected beam is denoted as R1. The remaining intensity enters the ARC layer 2 and is reflected at the intermediate surface or boundary 11 between the ARC layer 2 and the substrate 1. The resulting reflected beam R2 extinguishes the other beam R1 at least in part via destructive interference.

In the case of absorbing ARC layers, the refractive index of the ARC layer 2 is adjusted to be similar to the refractive index of the resist layer 5, thereby producing maximum transmission of the beam J into the layer 2 and absorbing the beam J within the ARC layer material. The present invention predominantly refers to the absorbing kind of ARC layers. It should be understood, however, that it applies also to destructive interference ARC layers as with a view to the three refractive indices of the resist 5, the ARC layer 2, and the substrate 1 an intensity variation of the reflected beam R2 may be useful. The reflected beam R1 is drawn in dashed lines as its intensity is rather low in case of absorbing ARC layers.

The prior art ARC layer material 2 illustrated in FIG. 1 is homogeneous. The ARC layer material 2 of the present invention illustrated in FIG. 2, on the other hand, comprises a matrix substance 3 embedding nanocrystalline particles 4 causing absorption of incoming light via the quantum size effect. Preferably two or more kinds of particles 4a, 4b are provided.

By exploiting this mechanism in the ARC layer 2, the reflected beam R2 is absorbed. The absorption profile can be shaped by providing different kinds or sizes of nanocrystalline particles, these and other composition parameters allowing an adjustment of further physical properties of the ARC layer itself.

The production of the ARC layer material compounds progresses in a well-known manner. Nanocrystalline particles are extracted by chemical hydrolysis condensation; the matrix substance is produced by a sol gel process. According to the invention, the matrix substance and the nanocrystalline particles are mixed and other chemical substances like solvents or surface-active agents for better adhesion to the substrate are added. The ARC layer material composition is then spun onto the substrate and then heated up to a temperature not above 200° C. in order not to crack polymer hydrocarbon chains of the matrix substance. During the heating, a certain amount of the solvent is removed and matrix substance molecules are interconnected with one another, thereby forming a network safely embedding the nanocrystalline particles.

Those of skill in the pertinent art will be able to choose the kinds and quantities of the matrix substance and of the nanocrystalline particles in order to appropriately tune physical properties such as refractive index, absorption profile, viscosity and etch resistance of the ARC layer.

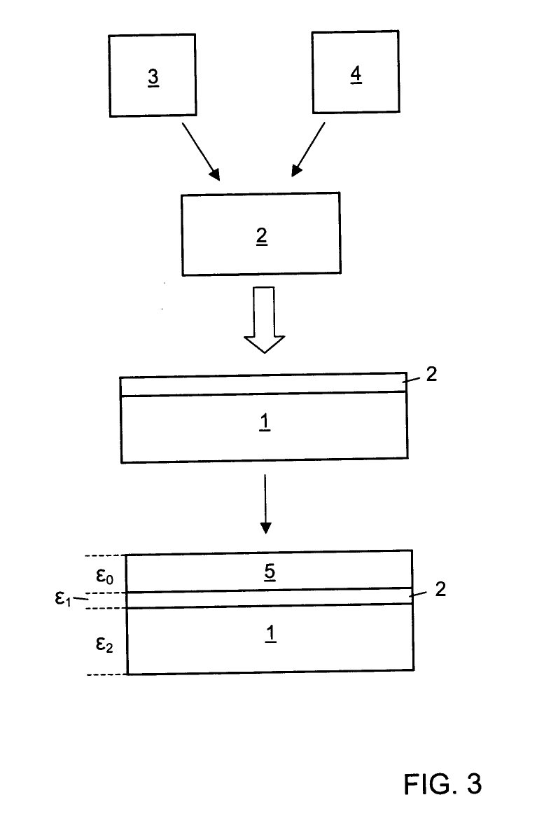

According to FIG. 3 an anti-reflective coating material is produced by first providing a matrix material 3, providing nano-crystalline particles 4 and mixing the matrix material 3 and the nano-crystalline particles 4 with one another to form the anti-reflective coating material 2. According to the invention nano-crystalline particles 4 absorbing light via the quantum size effect are used. The anti-reflective coating material 2 is then applied to a semiconductor substrate 1 to be patterned or to a layer 1 to be patterned on a semiconductor substrate thereby forming an anti-reflective coating layer 2. The material of the nano-crystalline particles 4 and their concentration in the matrix material 3 are chosen such that an anti-reflective coating material 2 having an adjusted refractive index ε1 is formed. Preferrably, by choosing the kind and/or the concentration of the nano-crystalline particles 4, such a refractive index ε1 of the anti-reflective coating layer 2 is adjusted which depends on the refractive index ε0 of a resist layer to be applied onto the anti-reflective coating material 2. The refractive index ε1 may further depend on the refractive index ε2 of a semiconductor substrate 1 to be patterned or of a layer 1 to be patterned on a semiconductor substrate.

We claim:

1. A semiconductor processing method, which comprises:
providing a semiconductor product; and
coating the semiconductor product with an anti-reflective coating material formed of a matrix substance and of nanocrystalline particles of a material different from the matrix substance, the nanocrystalline particles being configured to absorb light via the quantum size effect.

2. The method according to claim 1, which comprises selecting an average size of the nanocrystalline particles less than 100 nanometers in diameter.

3. The method according to claim 2, which comprises selecting the size of the nanocrystalline particles with less than a quarter of a wavelength of 248, 193, 157 or 127 nm of UV exposure light.

4. The method according to claim 1, which comprises choosing a material of the particles to thereby create additional energy levels within band gaps of the matrix substance, the band gaps having a predefined distance to a valence band or to a conduction band corresponding to a wavelength absorbed via the quantum size effect.

5. The method according to claim 4, which comprises choosing the material of the particles to effect absorption via the quantum size effect of a wavelength in the UV range.

6. The method according to claim 1, which comprises choosing the matrix substance and a material and a concentration of the particles to thereby achieve a refractive index granting maximum light entrance into the ARC layer material.

7. The method according to claim 1, which comprises choosing a material and a concentration of the particles for tuning a degree of absorption.

8. The method according to claim 1, which comprises choosing the matrix substance and a size and a concentration of the particles to thereby tune a viscosity value.

9. The method according to claim 1, which comprises choosing the matrix substance and a material and a concentration of the particles for tuning an etch resistance of a dry etch process for etching semiconductor substrates.

10. The method according to claim 1, wherein the matrix substance is selected from the group consisting of an organic resin, a silicate, and an oxide.

11. The method according to claim 1, wherein the matrix substance is an oxide selected from the group consisting of silicon oxide and titanium oxide.

12. The method according to claim 1, wherein a material of the particles is selected from the group consisting of a metal oxide, a metal sulphide, and a perovskite material.

13. The method according to claim 1, wherein the particles contain a material selected from the group consisting of tin oxide, titanium oxide, and cadmium sulphide.

14. The method according to claims 1, wherein the ARC layer contains between 3 and 70% per volume of nanocrystalline particles.

15. The method according to claims 1, wherein the ARC layer contains nanocrystalline particles of at least two different materials.

16. The method according to claim 1, which comprises coating a semiconductor substrate to be patterned or a layer to be patterned on a semiconductor substrate with the anti-reflective coating material to form an anti-reflective coating layer dimishing light reflection of exposure light.

17. The method according to claim 1, which comprises, prior to the coating step:
providing the matrix material and the nano-crystalline particles; and
mixing the matrix material and the nano-crystalline particles to form the anti-reflective coating material.

18. The method according to claim 17, which comprises choosing at least one of a type of the nano-crystalline particles and a concentration of the nano-crystalline particles in the matrix material to thereby forming an anti-reflective coating material having an adjusted refractive index.

19. The method according to claim 17, which comprises adjusting a refractive index ε1 of the anti-reflective coating material by choosing at least one of a type and a concentration of the nano-crystalline particles in dependence on a refractive index ε0 of a resist layer to be applied onto the anti-reflective coating material and/or in dependence on a refractive index ε2 of a semiconductor substrate to be patterned or of a layer to be patterned on a semiconductor substrate.

20. A semiconductor product, comprising:
a substrate having a surface;
a layer of an anti-reflective coating material formed on said surface;
said anti-reflective coating material comprising a matrix substance and nanocrystalline particles of a material different from said matrix substance, and said nanocrystalline particles being configured to absorb light via the quantum size effect.

21. The semiconductor product according to claim 20, which further comprises a resist layer on top of said layer of the anti-reflective coating material.
